(19) United States
(12) Patent Application Publication
(10) Pub. No.: US 2007/0148917 A1
(43) Pub. Date: Jun. 28, 2007

(54) Process for Regeneration of a Layer Transferred Wafer and Regenerated Layer Transferred Wafer

(75) Inventors: Etsurou Morita, Tokyo (JP); Shinji Okawa, Tokyo (JP); Isoroku Ono, Tokyo (JP)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(73) Assignee: SUMCO CORPORATION

(21) Appl. No.: 11/614,792

(22) Filed: Dec. 21, 2006

Related U.S. Application Data
(60) Provisional application No. 60/753,038, filed on Dec. 22, 2005.

(51) Int. Cl. H01L 21/30

(52) U.S. Cl. 438/459

(57) ABSTRACT

The regeneration cost is reduced when a layer transferred wafer is to be reused two times or more. Ions are implanted into a semiconductor wafer (13) to form an ion implanted area (13b) inside the semiconductor wafer (13), and a first laminated body (16) in which the wafer (13) is laminated on a first support wafer (14) is subjected to heat treatment so as to obtain a thick first layer transferred wafer (12). Then, an ion implanted area (23b) is formed inside the layer transferred wafer (12) by implanting ions into a second main surface (12c) of the first layer transferred wafer (12) on the side opposite to a separated surface (12a), and a second laminated body (26) in which the main surface (12c) of the wafer (12) is laminated onto a second support wafer (24) is subjected to heat treatment so as to obtain a thick second layer transferred wafer (22). And then, both surfaces of the layer transferred wafer (22) are polished to obtain a regenerated wafer (32). The separated surface (12a) of the wafer (12) and a separated surface (22a) of the wafer (22) have ring-shape steps (12b) and (22b) on each of the outer circumferential edges, and these ring-shape steps (12b) and (22b) are removed at the same time by polishing both surfaces of the second layer transferred wafer (22).

### BACKGROUND OF THE INVENTION

1. Field of the Invention

The present invention relates to a process for regeneration of a thick layer transferred wafer obtained by forming a laminated body by laminating a semiconductor wafer onto which ions are implanted into a support wafer and by separating from a thin layer of the semiconductor wafer in the ion implanted area by heat treatment of this laminated body and a layer transferred wafer regenerated by this process. The present invention relates more particularly to a process for regeneration of a layer transferred wafer regenerated two times or more in a so-called ion implantation separation method for producing bonded wafers such as SOI (Silicon On Insulator) and a wafer regenerated.

2. Description of the Related Art

As a conventional process for regeneration of a layer transferred wafer, a process for regeneration of a layer transferred wafer has been known in which after an ion implanted layer at least on a chamfered portion of a layer transferred wafer is removed, a main surface of the wafer on the layer-transferred side is polished (See the patent document 1, for example). According to this process for the regeneration, the layer transferred wafer can be used for a support wafer, which is a base wafer, a normal silicon mirror wafer or a semiconductor wafer, which is a bond wafer. And when the layer transferred wafer is to be reused as the support wafer (base wafer) or the semiconductor wafer (bond wafer), if the thickness of the initial semiconductor wafer is set large in advance, it can be reused repeatedly two times or more.

Japanese Unexamined Patent Application No. 2001-155978 (claim 1, Paragraph 0019).

However, the problem is that polishing both surfaces of the layer transferred wafer at each transfer in reusing the layer transferred wafer two times or more has increase the regeneration cost.

An object of the present invention is to provide a process for regeneration of a layer transferred wafer which can reduce the regeneration cost in reusing the layer transferred wafer two times or more and a regenerated layer transferred wafer.

### SUMMARY OF THE INVENTION

The invention according to claim 1 comprises, as shown in FIGS. 1 and 2, processes in the following order of:
(A) forming an ion implanted area inside a semiconductor wafer by implanting ions into a first main surface of the semiconductor wafer as a bond wafer;
(B) forming a first laminated body 16 by laminating the first main surface of the semiconductor wafer on a main surface of a first support wafer as a base wafer;
(C) obtaining a thick first layer transferred wafer by separating the semiconductor wafer from a thin layer in the ion implanted area by heat treatment of the first laminated body at a predetermined temperature;
(D) forming an ion implanted area inside the first layer transferred wafer by implanting ions into a second main surface of the first layer transferred wafer on the side opposite to a separated surface;
(E) forming a second laminated body by laminating the second main surface of the first layer transferred wafer on a main surface of a second support wafer as a base wafer, the second support wafer being different from the first support wafer;
(F) obtaining a thick second layer transferred wafer by separating the first layer transferred wafer from a thin layer in the ion implanted area by heat treatment of the second laminated body at a predetermined temperature, and
(G) obtaining a regenerated wafer by polishing both surfaces of the second layer transferred wafer, sequentially in this order,
wherein the separated surface of the first layer transferred wafer obtained in process (C) has a ring-shape step on the outer circumferential edge, a separated surface of the second layer transferred wafer obtained in process (F) has a ring-shape step on the outer circumferential edge, and the ring-shape steps of both the first and second main surfaces are removed at the same time by polishing both surfaces of the second layer transferred wafer of process (G).

By the process for regeneration of a layer transferred wafer according to claim 1, the ring-shape steps formed on both the separated surfaces of the wafer can be removed in one time after the semiconductor wafer is separated once on the front and back each, two times in total, to form the first layer transferred wafer and the second layer transferred wafer, and thus the regeneration cost can be reduced.

The invention according to claim 2 is related to claim 1, wherein, as shown in FIG. 2, the regenerated wafer whose both surfaces are polished in process (G) is used for the first support wafer in process (B) or the semiconductor wafer in process (A).

By the process for regeneration of a layer transferred wafer described in claim 2, the regenerated wafer can be used another two times or more by adjusting a carrier plate for both-surface polishing.

The invention according to claim 3 is related to claim 1, wherein between process (C) and process (D), process (H) comprising polishing the second main surface of the first layer transferred wafer on the side opposite to the separated surface is carried out.

By the process for regeneration of a layer transferred wafer described in claim 3, by removing damage such as chuck marks or the like on the second main surface formed during the production of the first layer transferred wafer by polishing before laminating the first layer transferred wafer on another support wafer, the high-quality SOI wafer can be obtained from the first layer transferred wafer even if the ring-shape step is left on the separated surface.

The invention according to claim 4 is related to claim 3, wherein the polishing in process (H) is carried out by using a wax-less polishing device having polishing surface plates over which polishing cloths are extended and a polishing head opposed to the polishing surface plates having a fixed annular template, by pressing a soft back pad provided within the template onto the separated surface of the first layer transferred wafer and by sliding the second main surface of the first layer transferred wafer in contact with the polishing cloths.

By the process for regeneration of a layer transferred wafer described in claim 4, by polishing the main surface on the side without the ring-shape step of the first layer transferred wafer by the wax-less polishing device, one main surface can be polished uniformly within the surface even if the other main surface (separated surface) has the ring-shape step.

The invention according to claim 5 is related to claim 3 or 4, wherein before the polishing in process (H), a process (I) comprising removing an oxide film formed on at least the second main surface of the first layer transferred wafer is carried out.

By the process for regeneration of a layer transferred wafer described in claim 5, by removing the oxide film on the second main surface of the layer transferred wafer before polishing in process (H), the second main surface can be polished uniformly without leaving any impurities such as particles.

The invention according to claim 6 is related to claim 3 or 4, wherein the polishing in process (H) comprises:
(J) primary polishing by pressing the second main surface of the first layer transferred wafer onto a polishing working surface of a primary polishing cloth coarser than a final polishing cloth while supplying a final polishing liquid, and
(K) after this primary polishing, final polishing by pressing the second main surface of the first layer transferred wafer onto the polishing working surface of the final polishing cloth while supplying the final polishing liquid.

The invention according to claim 7 is related to claim 3 or 4, wherein the polishing in process (H) comprises:
(L) primary polishing by pressing the second main surface of the first layer transferred wafer onto the polishing working surface of a final polishing cloth while supplying a primary polishing liquid coarser than the final polishing liquid, and
(M) final polishing by pressing, after the primary polishing, the second main surface of the first layer transferred wafer onto the polishing working surface of the final polishing cloth while supplying the final polishing liquid.

By the process for regeneration of a layer transferred wafer described in claim 6 or 7, damage such as chuck marks on the second main surface can be removed and high flatness of the second main surface can be realized by performing two-stage polishing.

The invention according to claim 8 is the regenerated wafer regenerated by the process in any one of claims 1 to 7.

In the regenerated wafer described in claim 8, since the ring-shape steps formed on both surfaces of the layer transferred wafer are removed at the same time by both-surface polishing, a polishing force is not biased to one of the surfaces at the both-surface polishing, but both the main surfaces are uniform and have high flatness.

### BRIEF DESCRIPTION OF THE DRAWINGS

FIG. 1 is a diagram showing a producing method of an SOI wafer including a layer transferred wafer according to the preferred embodiment of the present invention in the order of the processes;

FIG. 2 is a diagram showing a regeneration process order for polishing a second main surface of the first layer transferred wafer;

FIG. 3(a) is a plan view of an essential part of a wax-less polishing device for a single wafer showing a situation where the second main surface of the first layer transferred wafer is being polished by a first polishing surface plate, and FIG. 3(b) is a plan view of an essential part of a wax-less polishing device for a single wafer showing a situation where the second main surface of the first layer transferred wafer is being polished by a second polishing surface plate; and

FIG. 4(a) is a sectional view of A-A line in FIG. 3 and FIG. 4(b) is a sectional view of B-B line in FIG. 3.

### DETAILED DESCRIPTION OF THE PREFERRED EMBODIMENT

Next, the preferred embodiment of the present invention will be described based on the drawings.

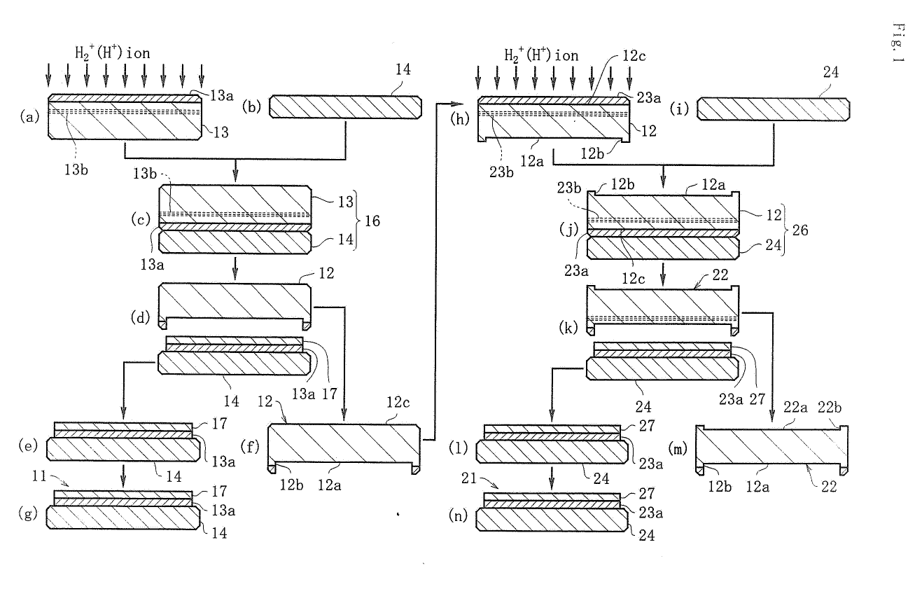

As shown in FIG. 1, layer transferred wafers 12 and 22 are generated secondarily when SOI wafers 11 and 21 are produced. In order to produce the SOI wafers 11 and 21, a semiconductor wafer 13 as a bond wafer and support wafers 14, 24 as base wafers are prepared. In this preferred embodiment, these wafers 13, 14 and 24 are produced by the Czochralski method, respectively, and they have the same diameter and the same thickness. These wafers 13, 14 and 24 are the wafers subjected to RCA cleaning after both-surface polishing.

First, an oxide film 13a (SiO₂ film), which is an insulating film, is formed on a first main surface of the wafer 13 by thermal oxidation of the semiconductor wafer 13, and then, hydrogen ions (H⁺), which are hydrogen gas ion, are implanted in the dose amount of 3.0×10¹⁶/cm² or more or a hydrogen-molecule ion (H²⁺) in the dose amount of 1.5×10¹⁶/cm² or more into the first main surface of this wafer 13 (FIG. 1(a)). Here, the reference numeral 13b in FIG. 1(a) is an ion implanted area formed inside the semiconductor wafer 13 by implantation of the hydrogen gas ion or the hydrogen-molecule ion, and this ion implanted area 13b is formed in parallel with the oxide film 13a, that is, the surface of the semiconductor wafer 13. The hydrogen gas ion (H⁺) requires about twice the implanting amount of the hydrogen-molecule ion (H²⁺) is required. Instead of the implantation of the hydrogen gas ion and the hydrogen-molecule ion, a helium ion (He⁺) may be implanted with the implantation of the hydrogen gas ion or the hydrogen-molecule ion. In this case, a dose amount of helium ion is preferably 0.5×10^{16/cm}² or more. The oxide film 13a may be formed on the entire surface (the first main surface, the second main surface and both the end edges) of the semiconductor wafer, though not shown.

Next, the first main surface of the semiconductor wafer 13 is laminated onto the main surface of the support wafer 14 shown in FIG. 1(b) through an oxide film 23a at a room temperature so as to form a laminated body 16 (FIG. 1(c)). The temperature of this laminated body 16 is raised to the range of 500 to 800° C. in an atmosphere of nitrogen (N₂) and kept in this temperature range for 5 to 30 minutes and then, thin-layer separation heat-treatment is carried out. By this, the semiconductor wafer 13 is split in the ion implanted area 13b and separated into an upper thick first layer transferred wafer 12 and a lower thin layer 17 (FIG. 1(d)).

Next, the temperature of the laminated body 16 in which the above semiconductor wafer 13 is split in the ion implanted area 13b is lowered, and the first layer transferred wafer 12 is removed from the support wafer 14 onto which the thin layer 17 is laminated through the oxide film 13a (hereinafter referred simply as the support wafer 14). Heat treatment is carried out that the temperature of the above support wafer 14 is raised to the range of 900 to 1200° C. in an atmosphere of oxygen (O₂) or nitrogen (N₂) and kept in this temperature range for 30 to 120 minutes (FIG. 1(e)). This heat treatment is heat treatment to strengthen the bonding of the thin layer 17 onto the support wafer 14. Moreover, the separated surface of the support wafer 14 is annealing-treated or polished (touch polishing) to be smoothened (FIG. 1(g)). By this, the support wafer 14 is made into the SOI wafer 11.

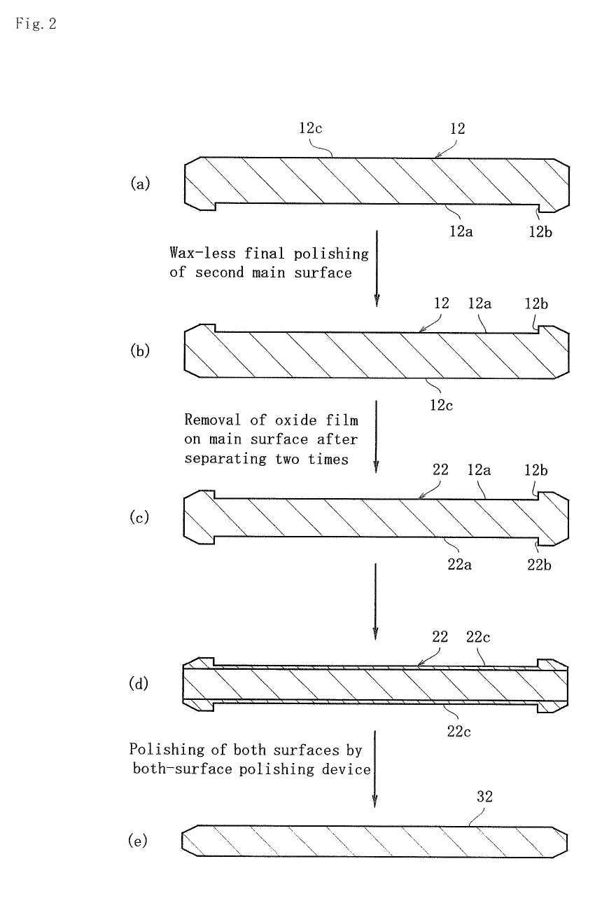

On the other hand, a ring-shape step 12b of about 0.3 μm is formed on an outer circumferential edge of the separated surface 12a of the first layer transferred wafer 12 (FIG. 1(f)). The mechanism this ring-shape step 12b is generated has not been clarified yet, but it is considered that the shape on a chamfered portion of the circumferential edge of the separated surface 12a of the layer transferred wafer 12 and the depth of the ion implanted area might have an influence. The oxide film formed by heat treatment or the like remains on the chambered portion of the circumferential edge of the separated surface 12a of the layer transferred wafer 12 and the second main surface 12c (FIG. 1(f)), but it is preferable to remove the oxide film by dipping this first layer transferred wafer 12 in fluorinated acid, as shown in FIG. 2A, before polishing the second main surface 12c of the layer transferred wafer 12, which will be described next.

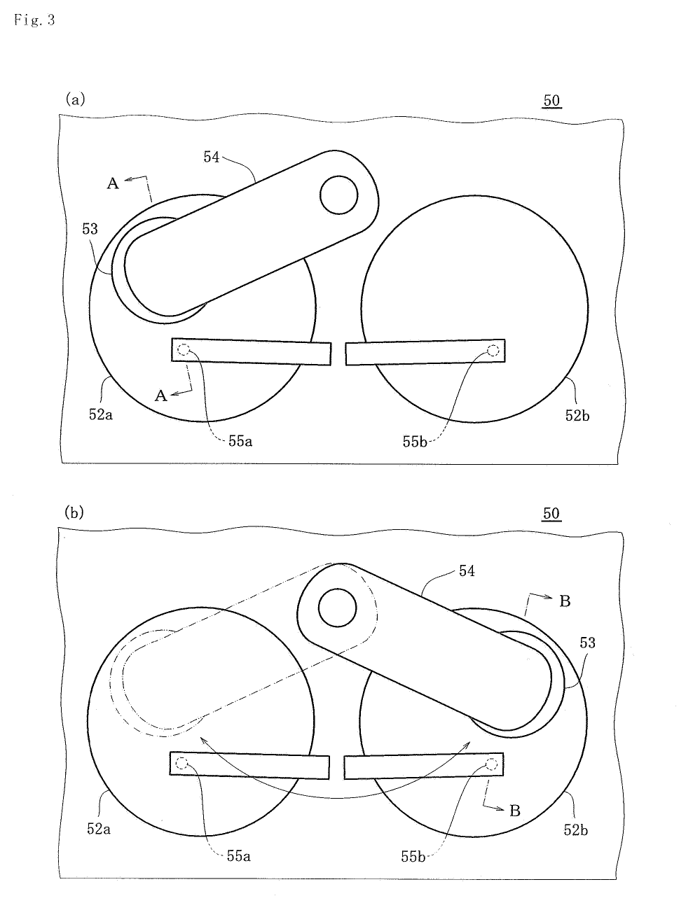

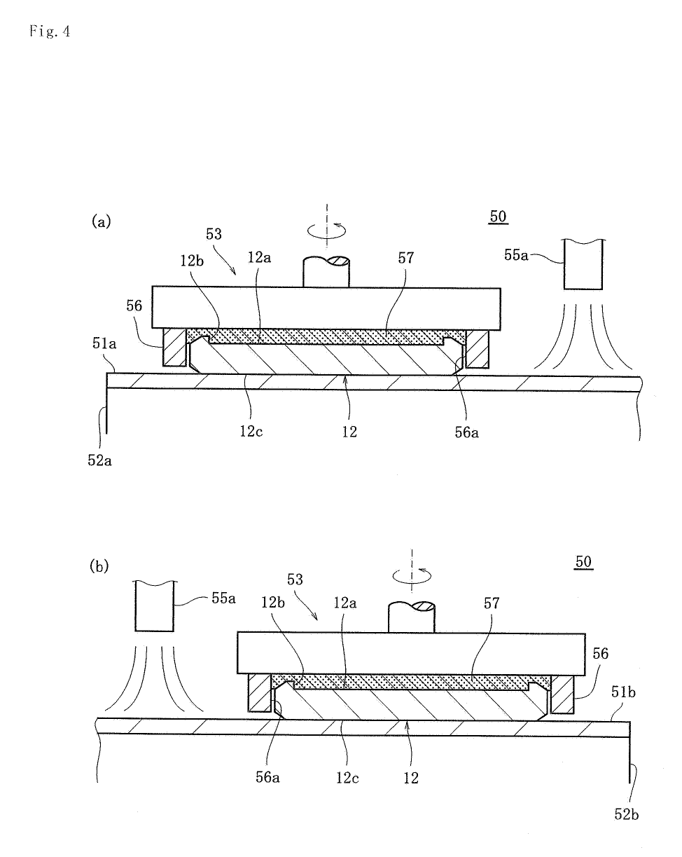

The second main surface 12c of the first layer transferred wafer 12 is polished by a wax-less polishing device for a single wafer 50 shown in FIGS. 3 and 4. As shown in FIGS. 3 and 4, the polishing device 50 is provided with a first polishing surface plate 52a and a second polishing surface plate 52b over which polishing cloths 51a and 51b of the polishing head 53 are extended and a polishing head 53 arranged capable of being opposed above either of the polishing surface plates 52a and 52b. The polishing head 53 is movably provided alternatively with the polishing surface plates 52a and 52b by an arm 54 as shown by an arrow in FIG. 3(b). As shown in FIG. 4, an annular template 56 is fixed to the lower face of the polishing head 53. A hole portion 56a with the diameter slightly larger than that of the layer transferred wafer 12 is formed inside this template 56, and a soft back pad 57 made of a suede pad, a silicon rubber, a non-woven cloth, etc. is contained in this hole. Above each of the polishing surface plates 52a and 52b, a nozzle 55a is disposed for supplying a polishing liquid toward the polishing cloth 51a and a nozzle 55b for supplying the polishing liquid toward the polishing cloth 51b, respectively.

Next, a method for polishing the second main surface 12c of the layer transferred wafer 12 using this polishing device 50 will be described.

The first layer transferred wafer 12 shown in FIG. 2(a) is pressed to the back pad 57 as shown in FIG. 4 so that its separated surface 12a is opposed thereto and arranged in the template 56. Pure water is supplied between a foamed layer (nap portion) of the back pad 57 and the separated surface 12a of the layer transferred wafer 12, and the layer transferred wafer 12 is brought into close contact with the back pad 57 by surface tension of the pure water.

Two methods for polishing the second main surface 12c of the layer transferred wafer 12 with the polishing cloth 51a of the first polishing surface plate 52a will be described.

[1] First Polishing Method

As shown in FIG. 4(a), the primary polishing cloth 51a which is coarser than a final polishing cloth is extended over the upper face of the first polishing surface plate 52a, and the nozzle 55a provided above this polishing cloth 51a is prepared so as to supply the final polishing liquid. On the other hand, as shown in FIG. 4(b), the final polishing cloth 51b is extended over the upper face of the second polishing surface plate 52b, and the nozzle 55b provided above this polishing cloth 51b is prepared so as to supply the final polishing liquid. As shown in FIG. 3(a), first, the polishing head 53 holding the first layer transferred wafer 12 is moved above the first polishing surface plate 52a by the arm 54, and the primary polishing is performed by pressing the second main surface 12c of the first layer transferred wafer 12 onto the polishing working surface of the primary polishing cloth 51a while supplying the final polishing liquid from the nozzle 55a. By this pressing, the ring-shape step 12b of the layer transferred wafer 12 is buried in the soft back pad 57, and the second main surface 12c of the layer transferred wafer 12, which is a polishing surface, is brought into contact with the primary polishing cloth 51a uniformly within the surface. Then, as shown in FIG. 3(b), after this primary polishing, the polishing head 53 is moved above the second polishing surface plate 52b by the arm 54 while holding the first layer transferred wafer 12, and the second main surface 12c of the first layer transferred wafer 12 is pressed onto the polishing working surface of the final polishing cloth 51b while supplying the final polishing liquid from the nozzle 55b so as to perform the final polishing. In this final polishing, also, the second main surface 12c is brought into contact with the final polishing cloth 51b uniformly within the surface as in the primary polishing.

[2] Second Polishing Method

The final polishing cloth is extended over the upper face of the first polishing surface plate 52a, and the nozzle 55a is prepared so as to supply the primary polishing liquid which is coarser than the final polishing liquid. On the other hand, for the polishing cloth of the second polishing surface plate 52b, the same final polishing cloth 51b as in the first polishing method is used, and the nozzle 55b is also prepared to supply the same final polishing liquid as in the first polishing method. After that, as in the first polishing method, the second main surface 12c of the layer transferred wafer 12 is pressed onto the final polishing cloth of the first polishing surface plate 52a to perform the primary polishing while supplying the primary polishing liquid, and then, the second main surface 12c is pressed onto the final polishing cloth of the second polishing surface plate 52b to perform the final polishing while supplying the final polishing liquid.

Here, as the primary polishing cloth, a hard urethane foam pad, a soft non-woven pad obtained by impregnating/hardening the non-woven cloth with urethane resin or the like is adopted, while as the final polishing cloth, a suede pad obtained by foaming urethane resin on a base cloth made of a non-woven cloth or the like is adopted. As the primary polishing liquid, slurry including loose grains made of sintered silica with the average grain diameter of about 0.02 to 0.1 μm or colloidal silica (silica sol) in an alkaline solution and amine, which is a processing accelerator, is adopted. As the final polishing liquid, slurry including loose grains with the average grain diameter of about 0.02 to 0.1 μm in an alkaline solution as well as an organic polymer, which is a haze inhibitor, is adopted.

Though the second main surface 12c of the first layer transferred wafer 12 is damaged by a chuck or the like, the damage such as chuck marks on the second main surface 12c can be removed and the high flatness of the second main surface 12c can be realized by polishing the second main surface 12c of the first layer transferred wafer 12 in two stages based on the above first or the second polishing method.

Next, similarly to the method described using FIG. 1(a), after the oxide film 23a is formed on the second main surface 12c of the wafer 12 by thermal oxidation of the finally polished first layer transferred wafer 12, hydrogen ions are implanted into this second main surface 12c (FIG. 1(h)). By this, the ion implanted area 23a is formed in parallel with the surface of the layer transferred wafer 12. Then, the second main surface 12c of the layer transferred wafer 12 is laminated on the main surface of another support wafer 24 shown in FIG. 1(i) through the oxide film 23a at a room temperature to form the laminated body 26 (FIG. 1(j)). Similarly to the above-mentioned method, thin-layer separation heat-treatment is applied to this laminated body 26. By this, the first layer transferred wafer 12 is split in the ion implanted area 23b and separated into the upper thick second layer transferred wafer 22 and the lower thin layer 27 (FIG. 1(k)). Moreover, the temperature of the laminated body 26 is lowered and the second layer transferred wafer 22 is removed from the support wafer 24 on which the oxide film 23a and the thin layer 27 are laminated. The support wafer 24 from which the wafer 22 has been removed is subjected to heat treatment as in the above-mentioned method so as to strengthen the bonding of the thin layer 27 to the support wafer 24 (FIG. 1(l), and then, the separated surface of the support wafer 24 is polished to smoothen (FIG. 1(n)). By this, the support wafer 24 is made into the SOI wafer 21.

On the other hand, the second layer transferred wafer 22 has, in addition to the ring-shape step 12b formed previously on the outer circumferential edge of its separated surface 12a, a ring-shape step 22b of about 0.3 μm is formed on the outer circumferential edge of a new separated surface 12a by the above heat treatment (FIG. 1(m)). On the chamfered portion of the circumferential edge of the separated surface 22a and the separated surface 12a of the layer transferred wafer 22, the oxide film formed by heat treatment or the like remains. It is preferable that these oxide films are removed by dipping the second layer transferred wafer 22 in fluorinated acid or the like as shown in FIG. 2(c).

The second layer transferred wafer 22 shown in FIG. 2C has its both main surfaces polished at the same time by a both-surface polishing device, not shown. More specifically, a portion indicated by the reference numeral 22c in FIG. 2(d) of the layer transferred wafer 22 is primarily polished by a both-surface polishing device capable of polishing a plurality of wafers, and then, a final polishing is carried out by a one-surface polishing device for a single wafer. Those as mentioned above are used as the primary polishing cloth and the primary polishing liquid in the primary polishing and the final polishing cloth and the final polishing liquid in the final polishing, respectively. In the both-surface polishing, the ring-shape steps 12b and 22b formed on both the main surfaces of the second layer transferred wafer 22 are removed at the same time. Also, at polishing, a polishing force is uniformly applied to the ring-shape steps 12b and 22b of both the main surfaces, and both the main surfaces of the finally polished regenerated wafer 32 from which the steps have been removed have a high flatness (FIG.2(e)). This regenerated wafer 32 can be used for the semiconductor wafer 13. By this, the number of reusable times of the wafer is increased and the manufacturing cost of the SOI wafer can be reduced.

As mentioned above, according to the present invention, when a layer transferred wafer is to be reused two times or more the separated surface of the first layer transferred wafer obtained at the first manufacture of the SOI wafer and the opposite surface thereof are laminated on another support wafer at the second manufacture of the SOI wafer and the second layer transferred wafer obtained by separation at this time is subjected to both-surface polishing so that the ring-shape steps formed on both the separated surfaces of the second layer transferred wafer can be removed at the same time, which can reduce the regeneration cost.

By adjusting a carrier plate of the both-surface polishing, the regenerated wafer can be reused another two times or more.

Also, by reducing damage on the second main surface formed during the manufacture of the first layer transferred wafer by polishing before laminating the first layer transferred wafer on another support wafer, a high-quality SOI wafer can be obtained from this layer transferred wafer even if the ring-shape step is left on this separated surface.

Also, by polishing one of the second main surface, on which the ring-shape step of the first layer transferred wafer is removed by the wax-less polishing device, the second main surface can be polished uniformly in the surface even if the other main surface (separated surface) has the ring-shape step.

Moreover, by removing the oxide film on the second main surface of the first layer transferred wafer before wax-less polishing, a uniform polishing is made possible without impurities such as particles remaining on the second main surface.

Furthermore, by performing the wax-less polishing in two stages of the primary polishing and the final polishing, the damage such as chuck marks on the second main surface can be removed and the second main surface can have a high flatness.

Additionally, since the wafer regenerated in the present invention has the ring-shape steps formed on both surfaces of the second layer transferred wafer removed by both-surface polishing at the same time, the polishing force is not biased to one face at the both-surface polishing and both the main surfaces have uniform and high flatness, respectively.

What is claimed is:

1. A process for regeneration of a layer transferred wafer comprising the following steps in this order:
(A) forming an ion implanted area inside a semiconductor wafer by implanting ions into a first main surface of the semiconductor wafer as a bond wafer;
(B) forming a first laminated body by laminating the first main surface of said semiconductor wafer on a main surface of a first support wafer as a base wafer;
(C) obtaining a thick first layer transferred wafer by separating said semiconductor wafer from a thin layer in said ion implanted area by a heat treatment of said first laminated body;
(D) forming an ion implanted area inside said first layer transferred wafer by implanting ions into a second main surface of the first layer transferred wafer on the side opposite to a separated surface;
(E) forming a second laminated body by laminating the second main surface of said first layer transferred wafer on a main surface of a second support wafer as a base wafer, the second support wafer being different from said first support wafer;
(F) obtaining a thick second layer transferred wafer by separating said first layer transferred wafer from a thin layer in said ion implanted area by a heat treatment of said second laminated body, and
(G) obtaining a regenerated wafer by polishing both surfaces of said second layer transferred wafer,
wherein the separated surface of the first layer transferred wafer obtained in step (C) has a ring-shape step on the outer circumferential edge, a separated surface of the layer transferred wafer obtained in step (F) has a ring-shape step on the outer circumferential edge, and the ring-shape steps of both said separated surfaces are removed at the same time by polishing both surfaces of said second layer transferred wafer of step (G).

2. The process of claim 1, wherein the regenerated wafer whose both surfaces are polished in step (G) is used for the semiconductor wafer in step (A).

3. The process of claim 1, wherein between step (C) and step (D), step (H) comprising polishing the second main surface of the first layer transferred wafer on the side opposite to the separated surface is carried out.

4. The process of claim 3, wherein the polishing in step (H) is carried out by using a wax-free polishing device having polishing surface plates covered with polishing cloths and a polishing head opposed to said polishing surface plates having a fixed annular template, by pressing a soft back pad provided within the template onto the separated surface of the first layer transferred wafer and by sliding the second main surface of said first layer transferred wafer in contact with said polishing cloths.

5. The process of claim 3 wherein before the polishing in step (H), a step (I)is carried out wherein an oxide film formed on at least the second main surface of the first layer transferred wafer is removed.

6. The process of claim 4 wherein before the polishing in step (H), a step (I) is carried out wherein an oxide film formed on at least a second main surface of the first layer transferred wafer is removed.

7. The process of claim 3, wherein the polishing in step (H) comprises:
a step (J)is carried out comprising primary polishing by pressing the second main surface of the first layer transferred wafer onto a polishing working surface of a primary polishing cloth coarser than a final polishing cloth while supplying a final polishing liquid, and
after this primary polishing, step (K) comprising a final polishing by pressing the second main surface of said first layer transferred wafer onto the polishing working surface of the final polishing cloth while supplying said final polishing liquid.

8. The process of claim 4 wherein the polishing in step (H) comprises:
a step (J) is carried out comprising primary polishing by pressing the second main surface of the first layer transferred wafer onto a polishing working surface of said first layer transferred wafer onto the polishing working surface of the final polishing cloth while supplying said final polishing liquid.

9. The process of claim 3, wherein the polishing in step (H) comprises:
step (L): primary polishing by pressing the second main surface of the first layer transferred wafer onto the polishing working surface of a final polishing cloth while supplying a primary polishing liquid coarser than the final polishing liquid, and
step (M): final polishing by pressing, after the primary polishing, the second main surface of said first layer transferred wafer onto the polishing working surface of the final polishing cloth while supplying said final polishing liquid.

10. The process of claim 4 wherein the polishing in step (H) comprises:
step (L): primary polishing by pressing the second main surface of the first layer transferred wafer onto the polishing working surface of a final polishing cloth while supplying a primary polishing liquid coarser than the final polishing liquid, and
step (M): final polishing by pressing, after the primary polishing, the second main surface of said first layer transferred wafer onto the polishing working surface of the final polishing cloth while supplying said final polishing liquid.

11. A wafer regenerated by the process of claim 1.

12. A wafer regenerated by the process of claim 2.

13. A wafer regenerated by the process of claim 3.

14. A wafer regenerated by the process of claim 4.

15. A wafer regenerated by the process of claim 5.

16. A wafer regenerated by the process of claim 6.

17. A wafer regenerated by the process of claim 7.

18. A wafer regenerated by the process of claim 8.

19. A wafer regenerated by the process of claim 9.

20. A wafer regenerated by the process of claim 10.
